(19) United States
(12) Patent Application Publication
(10) Pub. No.: US 2006/0163209 A1
(43) Pub. Date: Jul. 27, 2006

(54) Laser machining

(76) Inventors: Adrian Boyle, Rathangan (IE); Maria Farsari, Heraklion (GR)

Correspondence Address: Timothy J Keefer;Seyfarth Shaw, 55 E Monroe Street, Chicago, IL, 60603-5863, US

(21) Appl. No.: 10/523,846

(22) PCT Filed: Aug. 6, 2003
(86) PCT No.: PCT/EP03/08706

§ 371 Date: Feb. 21, 2006

(30) Foreign Application Priority Data
Aug. 6, 2002 (IE) 2002/0655
Oct. 22, 2002 (GB) 0224585.0

(51) Int. Cl. H01L 21/306; C23F 1/00

(52) U.S. Cl. 216/94; 156/345.1

(57) ABSTRACT

A silicon body W is machined with a UV or green laser beam 6 in a refrigerated liquid halide compound environment. Local heating with the laser beam of the liquid halide compound in the vicinity of a machining location is sufficient to cause a chemical reaction between the silicon body and the liquid halide compound which accelerates machining, enhances machining quality and reduces laser machining generated debris.

The present invention relates to laser machining, particularly of bodies containing at least a significant proportion of silicon.

Silicon reacts vigorously with all the halogens to form silicon tetrahalides. Thus, silicon reacts with fluorine, F₂, chlorine, Cl₂, bromine, Br₂, and iodine, I₂, to form respectively silicon fluoride, SiF₄, silicon chloride, SiCl₄, silicon bromide, SiBr₄, and silicon iodide, SiI₄. The reaction with fluorine takes place at room temperature but the other reactions require heating to over 300° C.
Si+F₂═SiF₄(gas)
Si+Cl₂═SiCl₄(gas)

It is also known from U.S. Pat. No. 5,266,532 and U.S. Pat. No. 5,322,988 that the presence of halocarbons accelerates the ablation of silicon. An example of a halocarbon-silicon reaction is
Si+CF₄═SiF₄(gas)+C(solid)

The reaction between halocarbons and silicon is not spontaneous. The reaction occurs only at energies above the melting threshold of silicon, and therefore is very localized and suitable for one-step silicon micro-machining applications such as wafer dicing, vias and surface patterning.

It is an object of the present invention to provide enhanced machining of silicon compared with that of the prior art.

According to a first aspect of the invention, there is provided a method of machining a silicon body with a laser beam, comprising the steps of: providing a liquid halide compound environment in at least a machining location of the silicon body; directing the laser beam at the machining location of the silicon body in the liquid halide compound environment; locally heating the liquid halide compound with the laser beam in the vicinity of the machining location of the silicon body sufficiently to cause a chemical reaction between the silicon body and the liquid halide compound at the machining location; and machining the silicon body at the machining location with the laser beam thereby causing the chemical reaction to take place at the machining location.

Advantageously, the step of providing a liquid halide compound environment comprises providing a liquid halocarbon environment.

Conveniently, the step of directing the laser beam comprises directing an UV wavelength laser beam.

Alternatively, the step of directing the laser beam comprises directing a green visible light wavelength laser beam.

Conveniently, the step of providing a liquid halide compound environment comprises providing an environmental chamber for containing the liquid halide compound

Preferably, the step of providing a liquid halide compound environment comprises providing a refrigerated liquid halide compound

Advantageously, the step of providing a refrigerated liquid halide compound comprises controlling a temperature of the refrigerated liquid halide compound before, during and after machining.

Alternatively, the step of providing a liquid halide compound environment comprises providing aerosol nozzle means for delivering the liquid halide compound to at least the machining location.

Conveniently, the step of providing a liquid halide compound environment comprises providing a halocarbon containing a halogen selected from the group of fluorine, chlorine, bromine and iodine.

Advantageously, the step of machining the silicon body comprises controlling a temperature of the silicon body substantially to prevent thermal damage to the silicon body by controlling thermal loading of the silicon body.

According to a second aspect of the invention, there is provided a laser machining apparatus comprising: a laser; means for directing a laser beam from the laser onto a machining location; and means for providing a controlled liquid halide compound environment around at least the machining location.

Advantageously, the means for providing a controlled liquid halide compound environment is arranged to provide a controlled liquid halocarbon environment.

Conveniently, the means for providing a controlled liquid halide compound environment comprises environmental chamber means.

Preferably, the environmental chamber means comprises bath means for a refrigerated liquid halide compound.

Conveniently, the environmental chamber means comprises an inlet port and an outlet port for the liquid halide compound, and a gas vent.

Preferably, the environmental chamber means comprises a window transparent to the laser beam for entry of the laser beam into the environmental chamber means.

Advantageously, the window is anti-reflection coated.

Preferably, the laser machining apparatus further comprises refrigeration means for providing a refrigerated liquid halide compound to the environmental chamber means.

Advantageously, the refrigeration means is arranged for controlling a temperature of the liquid halide compound before, during and after machining.

Preferably, the means for providing a controlled liquid halide compound environment comprises aerosol nozzle means for delivering the liquid halide compound at least to the machining location.

Conveniently, the laser emits at ultraviolet wavelengths.

Alternatively, the laser emits at green visible light wavelengths.

Preferably, the laser machining apparatus further comprises temperature control means for controlling a temperature of a body to be machined at the machining location, arranged substantially to prevent thermal damage of the body by controlling thermal loading of the body.

Conveniently, the laser machining apparatus further comprises telecentric lens means for directing the laser beam, wherein a flow of the refrigerated liquid halide compound substantially fills a field of view of the telecentric lens means.

The invention will be more clearly understood from the following description of some embodiments thereof, given by way of example only with reference to the accompanying drawings in which:—

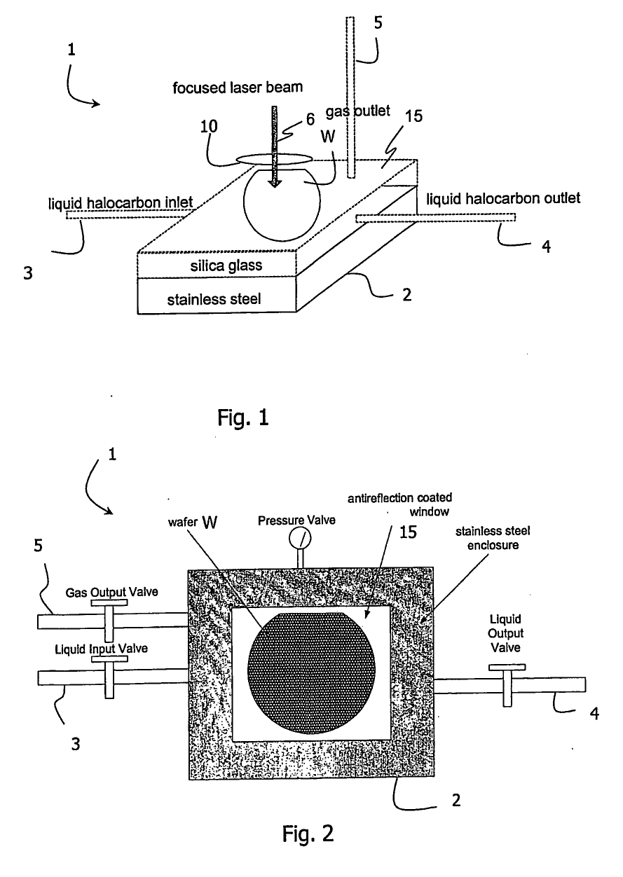

FIG. 1 is a perspective schematic view of a laser machining apparatus according to the invention; and

FIG. 2 is a plan view of the apparatus of FIG. 1.

In the figures, like reference numerals represent like parts.

Referring to FIGS. 1 and 2, a laser machining apparatus 1 comprises a stainless steel enclosure 2 having a liquid inlet 3, a liquid outlet 4, and a gas vent 5. An optical system 10 is mounted above the enclosure. An enclosed liquid bath is completed by an anti-reflection coated window 15 transparent to the laser beam to allow access of a UV laser beam to a silicon wafer W in the bath. Alternatively, a laser emitting green visible light may be used.

In use, the wafer W is placed in the enclosure 2 and a refrigerated liquid halide compound or tetrafluoroethane is pumped into the bath via the inlet 3. Alternatively, some other liquid halide compound, in particular a liquid halocarbon, producing a halogen such as fluorine, chlorine, bromine or iodine, may be used. The inlet 3 and the outlet 4 are in a refrigeration circuit so that the liquid temperature is maintained at or below the gas transition temperature of the particular liquid halide compound. The bath is at least partially filled with the liquid.

The temperature of the substrate W to be machined and the temperature of the active fluid may be controlled before, during and after machining in order to improve the efficiency of machining and also to improve the quality of machining.

The temperature of the wafer substrate W in an ambient environment may be varied in order to permit greater thermal control during laser machining by reducing thermal loading in the substrate and thus preventing thermal damage to the substrate.

The UV beam 6 is directed at the desired machining site on the wafer W for the desired machining operation. Locally, at the machining site, the laser beam heats the silicon so that the immediately surrounding liquid is both heated above the gas transition temperature, and the temperatures of both the silicon and the gas are sufficient for a reaction to take place. In this situation most of the by-products are gases and are vented away through the gas outlet 5. Those which are solid, particles are dispersed in the liquid and are not re-deposited onto the wafer surface.

The advantage of this system is that the system permits distribution of the liquid halide compound over a relatively large area of the surface of the substrate to be machined, thus permitting efficient and uniform machining. For laser machining of via structures, dice lanes or scribe lanes in a wafer substrate using a galvanometer based scanner, telecentric lens and linear XY motorised table, the flow of refrigerant halide compound can be optimised so as to fill completely the field of view of the telecentric lens (for example this may typically be 50 mm×50 mm in size). All features to be machined within the field of view can be machined very efficiently as refrigerated halide compound is present across the entire field of view and the XY stage does not need to be moved. Also, all features within the field of view are machined uniformly (i.e. they are of similar depth and quality) due to the even distribution of refrigerant halide compound within the field of view.

Thus, it will be appreciated that the invention provides for very efficient and high quality laser machining.

The invention is not limited to the embodiments described but may be varied in construction and detail. For example, the liquid may comprise mixtures of halocarbons and other liquids. Also, the environmental chamber may be partly filled with a refrigerated halocarbon liquid and the remainder filled with a gas. Also not only UV, but instead green lasers can be used. Also there can be more than one inlet, to allow the insertion of other liquids or gases into the environmental chamber.

Although the invention has been described for machining a silicon body, the invention has application at least for machining any body containing a significant proportion of silicon. An example of such a body is a multilayer structure which may contain several layers of semiconductor, metal, interlayer dielectric and ceramic materials. The multilayer structure can be partially or totally machined in the environmental chamber, with the fluid type and laser wavelength selected for the most effective machining of the individual material layers. Between machining of different layers the fluid type can be replaced with an alternative fluid, best suited to machining of the next layer.

Subsequent to laser machining in the environmental chamber, the substrate is removed and, if required, is cleaned using conventional techniques such as spin-rinse-dry, ultrasonic and megasonic cleaning.

1. A method of machining one of a silicon body and a silicon wafer substrate with an ultraviolet or green visible wavelength laser beam, wherein the machining comprises machining at least one of a through via structure and a through dice lane, comprising the steps of:
a. providing an environment of a liquid halide compound or a liquid comprising a mixture of halocarbons and other liquids in at least a machining location of the one of a silicon body and a silicon wafer substrate;
b. directing the laser beam at the machining location of the one of a silicon body and a silicon wafer substrate in the environment of the liquid halide compound or a liquid comprising a mixture of halocarbons and other liquids;
c. locally heating the liquid halide compound or the liquid comprising a mixture of halocarbons and other liquids with the laser beam in the vicinity of the machining location of the one of a silicon body and a silicon wafer substrate sufficiently to cause a chemical reaction between the one of a silicon body and a silicon wafer substrate and the liquid halide compound or the liquid comprising a mixture of halocarbons and other liquids at the machining location;
d. machining the one of a silicon body and a silicon wafer substrate at the machining location with the laser beam, thereby causing the chemical reaction to take place at the machining location to form at least one of gaseous and solid particle by-products; and
e. venting the gaseous by-products from the environment of the liquid halide compound or the liquid comprising a mixture of halocarbons and other liquids and dispersing the solid by-products in the liquid halide compound or the liquid comprising a mixture of halocarbons and other liquids.

2. A method as claimed in claim 1, wherein the step of providing the environment of a liquid halide compound or a liquid comprising a mixture of halocarbons and other liquids comprises providing an environmental chamber for containing the liquid halide compound or a liquid comprising a mixture of halocarbons and other liquids.

3. A method as claimed in claim 1, wherein the step of providing the environment of a liquid halide compound or a liquid comprising a mixture of halocarbons and other liquids comprises providing a refrigerated liquid halide compound or a refrigerated liquid comprising a mixture of halocarbons and other liquids.

4. A method as claimed in claim 3, wherein the step of providing the refrigerated liquid halide compound or the refrigerated liquid comprising a mixture of halocarbons and other liquids comprises controlling a temperature of the refrigerated liquid halide compound or the refrigerated liquid comprising a mixture of halocarbons and other liquids before, during and after machining.

5. A method as claimed in claim 1, wherein the step of providing the environment of a liquid halide compound or a liquid comprising a mixture of halocarbons and other liquids comprises providing aerosol nozzle means for delivering the liquid halide compound or the liquid comprising a mixture of halocarbons and other liquids to at least the machining location.

6. A method as claimed in claim 1, wherein the step of providing the environment of a liquid halide compound or a liquid comprising a mixture of halocarbons and other liquids comprises providing a halocarbon containing a halogen selected from the group of fluorine, chlorine, bromine and iodine.

7. A method as claimed in claim 1, wherein the step of machining the one of a silicon body and a silicon wafer substrate comprises controlling a temperature of the one of a silicon body and a silicon wafer substrate substantially to prevent thermal damage to the one of a silicon body and a silicon wafer substrate by controlling thermal loading of the one of a silicon body and a silicon wafer substrate.

8. (canceled)

9. A method as claimed in claim 1, wherein machining one of a silicon body and a silicon wafer substrate comprises machining a body containing a significant proportion of silicon.

10. A method as claimed in claim 9, wherein the step of machining a body containing a significant proportion of silicon comprises machining a multilayer structure.

11. A method as claimed in claim 10, wherein machining a multilayer structure comprises machining a multilayer structure having a plurality of layers of semiconductor, metal, interlayer dielectric and ceramic materials.

12. A laser machining apparatus for machining one of a silicon body and a silicon wafer substrate, wherein the machining comprises machining at least one of a through via structure and a through dice lane comprising: an ultraviolet or green visible wavelength laser;
environment control means for providing a controlled environment of a liquid halide compound or a liquid comprising a mixture of halocarbons and other liquids in at least a machining location of the silicon body;
beam directing means for directing a laser beam from the laser onto the machining location locally to heat the liquid halide compound or the liquid comprising a mixture of halocarbons and other liquids with the laser beam in the vicinity of the machining location of the one of a silicon body and a silicon wafer substrate sufficiently to cause a chemical reaction between the one of a silicon body and a silicon wafer substrate and the liquid halide compound or the liquid comprising a mixture of halocarbons and other liquids at the machining location and to machine the silicon body at the machining location with the laser beam, thereby causing the chemical reaction to take place at the machining location to form gaseous and solid particle by-products such that the solid by-products are dispersed in the liquid halide compound or the liquid comprising a mixture of halocarbons and other liquids; and
a gas vent arranged to vent the gaseous by-products from the environment of the liquid halide compound or the liquid comprising a mixture of halocarbons and other liquids.

13. A laser machining apparatus as claimed in claim 12, wherein the environment control means for providing the controlled environment of a liquid halide compound or a liquid comprising a mixture of halocarbons and other liquids is arranged to provide a controlled liquid halocarbon environment.

14. A laser machining apparatus as claimed in claim 12, wherein the environment control means for providing the controlled environment of a liquid halide compound or a liquid comprising a mixture of halocarbons and other liquids comprises environmental chamber means.

15. A laser machining apparatus as claimed in claim 14, wherein the environmental chamber means comprises bath means for a refrigerated liquid halide compound.

16. A laser machining apparatus as claimed in claim 14, wherein the environmental chamber means comprises an inlet port and an outlet port for the liquid halide compound, and a gas vent.

17. A laser machining apparatus as claimed in claim 14, wherein the environmental chamber means comprises a window transparent to the laser beam for entry of the laser beam into the environmental chamber means.

18. A laser machining apparatus as claimed in claim 17, wherein the window is anti-reflection coated.

19. A laser machining apparatus as claimed in claim 14, comprising refrigeration means for providing a refrigerated liquid halide compound or a liquid comprising a mixtures of halocarbons and other liquids to the environmental chamber means.

20. A laser machining apparatus as claimed in claim 19, wherein the refrigeration means is arranged for controlling a temperature of the liquid halide compound or the liquid comprising a mixtures of halocarbons and other liquids before, during and after machining.

21. A laser machining apparatus as claimed in claim 12, wherein the environment control means for providing the environment of a liquid halide compound or a liquid comprising a mixture of halocarbons and other liquids comprises aerosol nozzle means for delivering the liquid halide compound or a liquid comprising a mixture of halocarbons and other liquids at least to the machining location.

22. A laser machining apparatus as claimed in claim 12 comprising temperature control means for controlling a temperature of the one of a silicon body and a silicon wafer substrate to be machined at the machining location, arranged substantially to prevent thermal damage of the one of a silicon body and a silicon wafer substrate by controlling thermal loading of the one of a silicon body and a silicon wafer substrate.

23. A laser machining apparatus as claimed in claim 19, further comprising telecentric lens means for directing the laser beam, wherein a flow of the refrigerated liquid halide compound substantially fills a field of view of the telecentric lens means.

24. A method as claimed in claim 1, wherein the step of providing an environment of a liquid halide compound or a liquid comprising a mixture of halocarbons and other liquids comprises providing an environment of tetrafluoroethane.

25. A laser machining apparatus as claimed in claim 12, wherein the environment control means for providing a controlled environment of a liquid halide compound or a liquid comprising a mixture of halocarbons and other liquids comprises environment control means for providing a tetrafluoroethane environment.
